(19) United States
(12) Patent Application Publication
(10) Pub. No.: US 2007/0267057 A1
(43) Pub. Date: Nov. 22, 2007

(54) Optical device and method of forming the same

(76) Inventors: Charles C. Haluzak, Corvallis, OR (US); Peter Mardilovich, Corvallis, OR (US); Conor Kelly, Corvallis, OR (US); John R. Sterner, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/435,655

(22) Filed: May 17, 2006

(51) Int. Cl. H01L 31/00

(52) U.S. Cl. 136/255

(57) ABSTRACT

An optical device includes a first substrate and a sub-wavelength form-birefringent metal oxide retarder plate formed on at least a portion of the substrate. A silicon oxide or silicon oxynitride layer contacts at least a surface of the retarder plate, and a second substrate, having at least one micro-electro-mechanical system device, is bonded to the silicon oxide or silicon oxynitride layer via a second silicon oxide or silicon oxynitride layer.

### BACKGROUND

The present disclosure relates generally to optical devices and methods of forming the same.

A quarter-wave plate (QWP) is used in a variety of optical devices as a polarization retarder. The QWP is generally included because it is capable of retarding light of one linear polarization by a quarter wavelength (90°) relative to the orthogonal polarization.

Many quarter-wave plates function as stand alone quarter-wave plates that are integrated into complete optical systems. A polycarbonate film is one example of this type of QWP. The polycarbonate quarter-wave plate is sandwiched between two index-matched adhesives and two index-matched glass pieces. Generally, the adhesives are located at the interfaces of the quarter-wave plate and the glass pieces. An example of this system includes a micro-electro-mechanical system (MEMS) chip mounted to a prism. To reduce undesirable reflections that may result from refraction, the system includes an index-matched adhesive on both sides of the QWP, and between the MEMS chip and the prism glass.

Index-matched adhesives generally induce two automatic interfaces that need to be well index-matched for efficient device function. Furthermore, when an index-matched adhesive is attached directly to a MEMS device, it generally means that the MEMS device cannot have an opening into the array area. Such an opening is generally a path for liquid adhesives to either flow or outgas into. A lack of such an opening may be a constraint for both device function (such as packaged pressure setting), and for device/package manufacturing.

The adhesives may “yellow” or optically “age” in the presence of visible light, especially when the visible light has a wavelength closer to ultraviolet light. The index-matched adhesive may also be difficult to dispense and cure without trapping air bubbles. These air bubbles may be a random defect for an optical MEMS device if the bubbles are located in the optical path.

Other materials, including birefringent crystals cut along the optical axis, may function as quarter-wave plates. These crystals, however, are frequency (color) dependent, and may be relatively costly. Furthermore, these crystals are stand-alone materials that require integration into the optical system without inducing loss of reflected light.

As such, it would be desirable to provide an optical device having a quarter-wave plate that obviates one or more of the above drawbacks.

### SUMMARY

An optical device is disclosed herein. The optical device includes a first substrate and a sub-wavelength form-birefringent metal oxide retarder plate formed on at least a portion of the substrate. A silicon oxide or silicon oxynitride layer contacts at least a surface of the retarder plate, and a second substrate, having at least one micro-electro-mechanical system device, is bonded to the silicon oxide or silicon oxynitride layer via a second silicon oxide or silicon oxynitride layer.

### BRIEF DESCRIPTION OF THE DRAWINGS

Features and advantages of the present disclosure will become apparent by reference to the following detailed description and drawings, in which like reference numerals correspond to similar, though not necessarily identical components. For the sake of brevity, reference numerals or features having a previously described function may not necessarily be described in connection with other drawings in which they appear.

FIG. 1 is a flow diagram depicting an embodiment of a method for forming an embodiment of an optical device;

FIGS. 2A through 2F are schematic diagrams depicting an embodiment of a method for forming an embodiment of an optical device;

FIG. 3 is a top view of an embodiment of the device shown in FIG. 2C;

FIGS. 4A through 4E are schematic diagrams depicting an embodiment of a method forming another embodiment of an optical device; and

FIG. 5 is a perspective view of an embodiment of an optical device including a stack, with the MEMS device removed for clarity.

### DETAILED DESCRIPTION

Embodiments of the optical device and methods disclosed herein advantageously have the retarder plate integrated directly on an optical window or lid (also referred to herein as a first substrate) of the device, thereby allowing its close proximity to a MEMS chip or device. Furthermore, the optical device disclosed herein may advantageously be hermetically sealed. Without being bound to any theory, it is believed that this placement substantially minimizes undesirable light becoming part of the projected image. This is accomplished by the retarder plate (RP), which modulates the polarization phase of incident light such that stray reflections that are prior to the RP are reflected away from the projected image. Furthermore, the RP is formed via anodic oxidation and patterning (e.g., selective etching), which allows broader design flexibility via refractive index, as many different metals (the oxides of which have distinct refractive indices) may be used in such processes.

It is to be understood that the retarder plate may be set for any desirable phase-lag, non-limitative examples of which include one-quarter (i.e., a quarter-wave plate) or one-half (i.e., a half-wave plate).

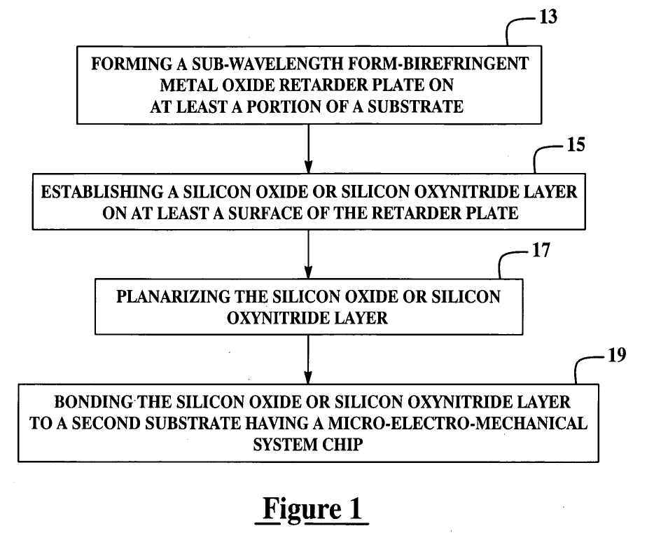

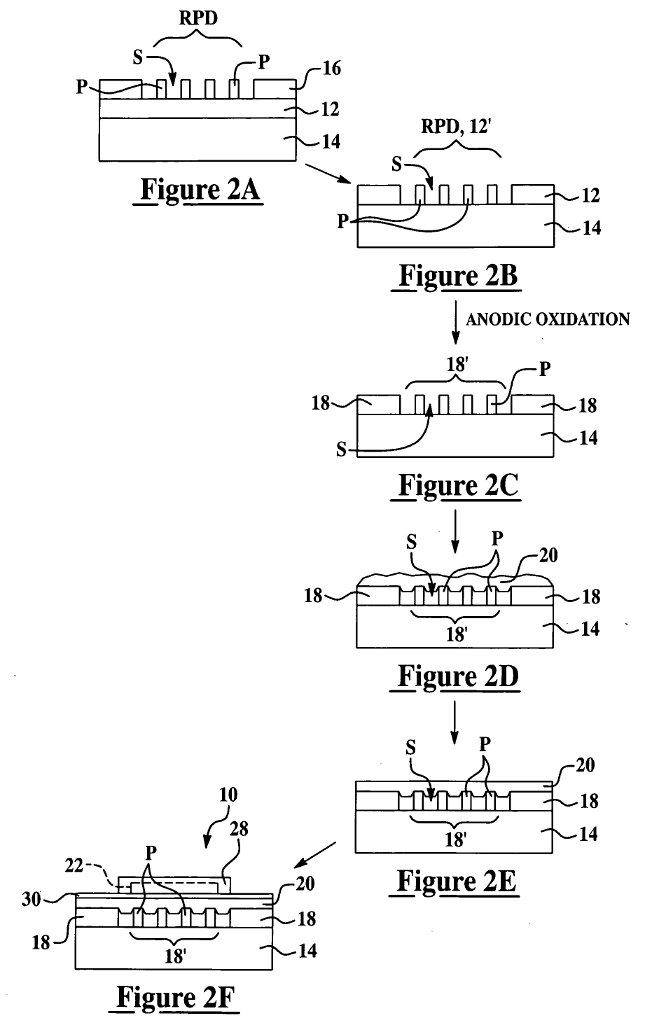

Referring now to FIG. 1, an embodiment of the method for forming an optical device includes forming a sub-wavelength form-birefringent metal oxide retarder plate on a first substrate (also referred to herein as an optical window), as depicted at reference numeral 13; establishing a silicon oxide or silicon oxynitride layer on at least a surface of the retarder plate, as shown at reference numeral 15; planarizing the silicon oxide or silicon oxynitride layer, as shown at reference numeral 17; and bonding the silicon oxide or silicon oxynitride layer to a second substrate via a second silicon oxide or silicon oxynitride layer, the second substrate having a micro-electro-mechanical system device established at least one of therein or thereon, as shown at reference numeral 19. It is to be understood that embodiments of the method will be described in more detail in reference to FIGS. 2A-2F, 3, 4A-4E, and 5 hereinbelow.

Referring now to FIGS. 2A through 2F and FIGS. 4A through 4E, embodiments of forming the optical device 10, 10′ (shown in FIG. 2F and FIG. 4E, respectively) are depicted. Initially, as depicted in FIGS. 2A and 4A, a metal layer 12 is established on a first substrate 14, and a resist layer 16 having a predetermined retarder plate design RPD is established on at least a portion of the metal layer 12.

It is to be understood that the first substrate 14 is generally a substrate that is configured to be an optical window, a lid package, a pixel, or a prism in the device 10, 10′. Non-limitative examples of materials suitable for the first substrate 14 include glass, fused silica, quartz, sapphire, or combinations thereof.

The metal layer 12 may include any suitable metal. The metal selected may be determined, at least in part, by the oxide and refractive index that is desired for the retarder plate. Non-limitative examples of suitable metals for the metal layer 12 include tantalum, aluminum, zinc, tungsten, niobium, any other metals capable of being oxidized, alloys thereof, or combinations thereof. Furthermore, the metal layer 12 may be established via any suitable deposition technique. Examples of such deposition techniques include, but are not limited to physical vapor deposition (PVD) (non-limitative examples of which include evaporation or sputtering), chemical vapor deposition (CVD), atomic layer deposition (ALD), and/or the like, or combinations thereof.

As shown in FIGS. 2A and 4A, the resist layer 16 is established on the metal layer 12 so that it has a predetermined retarder plate design RPD. The retarder plate design RPD may have any suitable pattern; different non-limitative examples of which are shown in FIGS. 2A and 4A. FIG. 2A depicts the retarder plate design RPD substantially at the center of the metal layer 12, and FIG. 4A depicts the retarder plate design RPD substantially across the entire metal layer 14. In an embodiment, the predetermined retarder plate design RPD includes a plurality of nano-structured pillars P having spaces S therebetween. It is to be understood that the pillars P and spaces S may be arranged in any suitable configuration, and in an embodiment, the pillars P and spaces S of a single retarder plate are substantially parallel to each other.

Generally, the resist layer 16 is established as a substantially continuous layer using spin-coating, needle-dispensing, curtain coating, spray-coating, or other liquid dispensing techniques, or combinations thereof. The continuous resist layer is then nanoimprinted (e.g., via nano-imprint lithography) to form the predetermined retarder plate design RPD, as shown in FIGS. 2A and 4A.

Referring now to FIGS. 2B through 2F, one embodiment of forming the optical device 10 is depicted. Specifically referring to FIG. 2B, after the metal layer 12 and the resist layer 16 having the predetermined retarder plate design RPD are established, the method further includes selectively etching at least a portion of the metal layer 12 to form a patterned metal layer 12′. It is to be understood that a highly selective etching process may be used so that the first substrate 14 is not appreciably etched. As a non-limitative example, a chlorine reactive ion etch (RIE) may be used to remove, for example, tantalum or aluminum, without appreciably etching a glass substrate.

As depicted in FIG. 2B, the patterned metal layer 12′ takes on the retarder plate design RPD, while edges of the metal layer 12 established along the edges of the first substrate 14 remain unpatterned. It is to be understood that such unpatterned portions of the metal layer 12 do not make up the retarder plate.

FIG. 2B also depicts the resist layer 16 having been removed. Removal of the resist layer 16 may be accomplished, for example, by solvent or aqueous dissolution, oxygen plasma (“ashing”), or combinations thereof.

The unpatterned metal layer 12 and the patterned metal layer 12′ are then anodically oxidized to form respectively, in-situ, a metal oxide 18 and a metal oxide 18′ having the retarder plate design (i.e., retarder plate 18′). It is to be understood that the unpatterned metal layer 12 and the patterned metal layer 12′ are substantially completely anodized through so that substantially the entire unpatterned and patterned metal layers 12, 12′ are converted to its oxide 18, 18′. Non-limitative examples of the metal oxides 18, 18′ include tantalum pentoxide, aluminum oxide, zinc oxide, tungsten oxide, niobium oxide, or any other metal oxide.

The resulting sub-wavelength metal oxide 18′ having the retarder plate design RPD functions as the retarder plate, where the nano-structured pillars P lead to form-birefringence, i.e. an index of refraction that differs parallel or perpendicular to the pillars P. The refractive indices may be predetermined by selecting a metal layer 12 (patterned metal layer 12′) that will form the retarder plate metal oxide 18′ having the desirable refractive indices, and by varying the pattern (ratio of metal oxide to air (or other oxide)). It is to be understood that this ratio may vary through the thickness of the pillars P, which may be altered depending, in part, on the etching conditions. The amount of retardation (e.g., quarter-wave) is determined, at least in part, by the final thickness of the patterned structure (i.e., the retarder plate metal oxide 18′).

As a non-limitative example, a sub-wavelength form birefringent quarter wave plate formed of Ta₂O₅ and air would be a 200 nm pitch grating of 100 nm oxide pillars P and 100 nm air. A grating of 431.5 nm thick would function as a quarter-wave for 650 nm wavelength light.

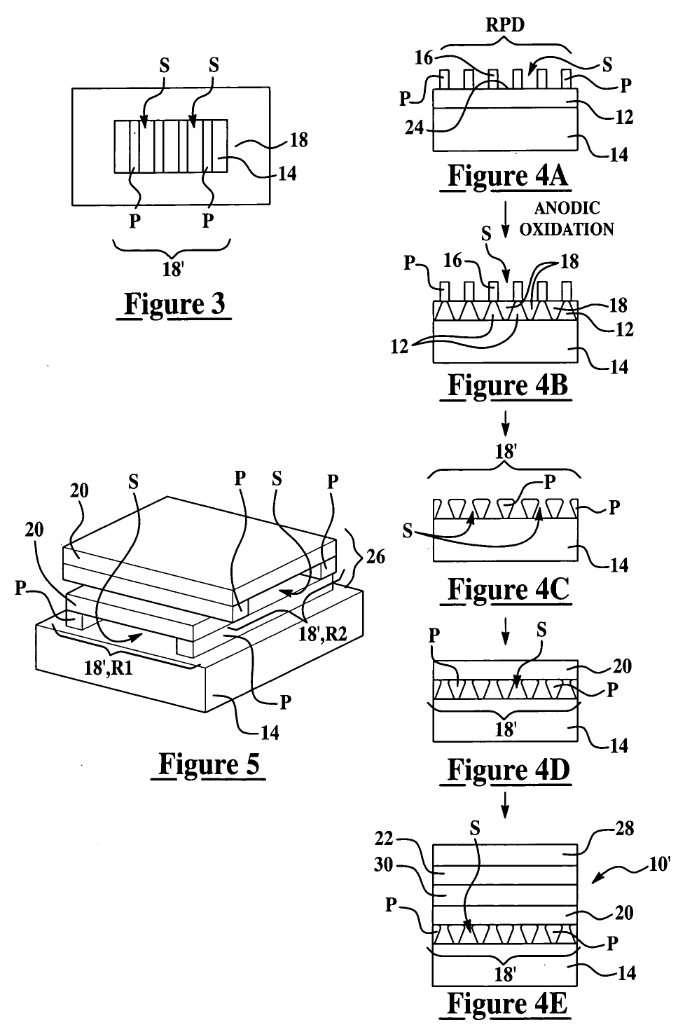

Referring now to FIG. 3, a top view of the structure of FIG. 2C is shown. As depicted, the metal oxide 18 (formed from the unpatterned metal layer 12) substantially aligns edges of the substrate 14 (the top of which may be seen at the spaces S). The patterned metal oxide 18′ (i.e., retarder plate) includes the pillars P having the spaces S located therebetween. This top view illustrates the retarder plate design RPD substantially at the center of the first substrate 14 upon which it is formed.

It is to be understood that in this embodiment, the subsequently established silicon oxide or silicon oxynitride layer (described further hereinbelow) may be configured to contact a second substrate having a MEMS chip or device configured therein or thereon via another silicon oxide or silicon oxynitride layer. As such, the silicon oxide or silicon oxynitride layer(s) may hermetically seal the package 10 (shown in FIG. 2F).

Referring back to FIG. 2D, this embodiment of the method further includes establishing a silicon oxide or silicon oxynitride layer 20 on at least a surface of the metal oxide retarder plate 18′. The silicon oxide or silicon oxynitride layer 20 may be established so that it substantially fills the spaces S of the RP design, partially fills the spaces S, substantially does not fill the spaces S, or combinations thereof (i.e., some spaces S are filled and partially filled, whiles others remain unfilled). Whether the spaces S are filled, partially filled, or remain unfilled, depends, at least in part, on the desired design, the deposition technique used, and/or physics (e.g., the refractive index of the metal oxide 18, 18′).

It is to be understood that the silicon oxide or silicon oxynitride layer 20 may be established via any suitable deposition technique (e.g., plasma enhanced chemical vapor deposition), including those previously described herein. Non-limitative examples of suitable silicon oxide materials include tetraethyl orthosilicate (TEOS), silane-based plasma enhanced chemical vapor deposited (PECVD) silicon dioxide, or combinations thereof. The silicon oxynitride material has a general formula of SiₓO_{y}N_{z}.

The silicon oxide or silicon oxynitride layer 20 may act as a hermetic bonding layer and may also protect the relatively fragile metal oxide retarder plate 18′.

In an embodiment, the silicon oxide or silicon oxynitride layer 20 is then planarized so that the layer 20 is substantially flat or planar with respect to the first substrate 14 surface. Planarization may be accomplished via a chemical-mechanical planarization (CMP) process. FIG. 2E depicts the planarized silicon oxide or silicon oxynitride layer 20.

Referring now to FIG. 2F, a second substrate 28 is bonded to the silicon oxide or silicon oxynitride layer 20 via a second silicon oxide or silicon oxynitride layer 30. The two silicon oxide or silicon oxynitride layers 20, 30 bond the first and second substrates 14, 28. It is to be understood that the second silicon oxide or silicon oxynitride layer 30 may be planarized prior to bonding with the silicon oxide or silicon oxynitride layer 20. Bonding may be accomplished by plasma-assisted bonding or silicate bonding.

It is to be understood that the second substrate 28 may have a micro-electro-mechanical system chip 22 established therein and/or thereon. For example, the MEMS chip 22 may be established on a surface of second substrate 28, or chip 22 may be established in a groove of second substrate 28. As depicted in FIG. 2F, the MEMS chip 22 is established in the second substrate 28. In an embodiment, it is to be understood that the bonding process hermetically seals the MEMS chip 22 within the package 10.

Non-limitative examples of the MEMS chip 22 include light modulators, Fabry-Perot chips, micro-opto-electromechanical systems, micromirrors, micro-actuators, bio-MEMS-optical arrays, or combinations thereof.

Referring now to FIGS. 4A through 4E, another embodiment for forming the optical device 10′ is depicted. FIG. 4A, as previously described, has the resist layer 16 and the metal layer 12 established on the first substrate 14.

In this embodiment, the metal layer 12 is not etched prior to anodic oxidation. As depicted, the resist layer 16 is established (i.e., deposited and patterned) so that at least one area 24 of the first substrate 14 remains exposed. During anodic oxidation, the metal layer 12 at the exposed area(s) 24 partially oxidizes to form the metal oxide 18 that is later patterned to form the retarder plate 18′. It is to be understood that oxidation begins isotropically in the spaces S of the resist layer 16.

As depicted in FIG. 4C, the resist layer 16 may then be removed via any suitable removal technique, such as those previously described.

In addition to the removal of the resist layer, FIG. 4C also depicts the patterned metal oxide retarder plate 18′. It is to be understood that the unoxidized areas of the metal layer 12 (shown in FIG. 4B) are removed via a wet-etch or a plasma etch process to form the pillars P of the metal oxide RP 18′ and the spaces S therebetween. The metal oxide 18′ functions as the RP, and as previously described, may have form-birefringent characteristics.

Referring now to FIG. 4D and 4E together, the silicon oxide or silicon oxynitride layer 20 is established and planarized to form the substantially flat silicon oxide or silicon oxynitride layer 20 on the metal oxide retarder plate 18′. The second substrate 28 (in this example embodiment having a MEMS chip 22 established on a surface thereof) is bonded to the silicon oxide or silicon oxynitride layer 20 via a second silicon oxide or silicon oxynitride layer 30 using plasma-assisted bonding or silicate bonding. In this embodiment, the silicon oxide or silicon oxynitride layer 20 may penetrate the spaces S of the retarder plate design RPD as previously described.

Referring now to FIG. 5, embodiments of the package 10 disclosed herein may also include a retarder plate that is made up of two or more phase retarder plates R1, R2, 18′. Each of the retarder plates R1, R2, 18′ has a silicon oxide or silicon oxynitride layer 20 established thereon, which together form a stack 26. As such, a stack 26 generally includes at least two retarder plates R1, R2, 18′ and at least two silicon oxide layers or silicon oxynitride layers 20. It is to be understood that any suitable number of retarder plates R1, R2, 18′ and silicon oxide or silicon oxynitride layers 20 may be incorporated into a stack 26.

Generally, the stack 26 may be selected so that the package 10 is capable of operating with substantially uniform retardation over a relatively broad spectrum. It is to be understood that the retarder plates R1, R2, 18′ in a stack 26 work together to have a total combined effect (e.g., one-quarter, one-half, or other wave retardations) on light. Individual retarder plates R1, R2, 18′ have degrees of freedom, including, but not limited to the refractive index of metal and silicon oxide or silicon oxynitride layers 20, and the surface topology (periodicity of pillars P, height of pillars P, width of pillars P, etc.). The stack 26 may be formed of a multitude of retarder plates R1, R2, 18′ and silicon oxide or silicon oxynitride layers 20, each with a specific and non-zero angle with respect to the pillars P of the other component retarder plates R1, R2, 18′. By creating a stack 16 of a multitude of different retarder plates R1, R2, 18′, each with specific refractive index, pillar P characteristics, and angle with respect to the first retarder plate R1, a desired retardation may be achieved for multiple wavelengths. The device 10 may be constructed such that each component retarder plate R1, R2, 18′ in the stack 26 contributes to make the overall retardance substantially uniform and broadband over many wavelengths, though the performance of each plate R1, R2, 18′ individually is substantially different than a broadband retarder plate.

FIG. 5 depicts the package assembly 10 with the second substrate 28, the MEMS chip 22, and the second silicon oxide or silicon oxynitride layer 30 removed for clarity. As depicted, a stack 26 is established on the first substrate 14. The stack 26 includes a first retarder plate R1, 18′ having pillars P, with a layer 20 thereon, and a second retarder plate R2, 18′ having pillars P, with a layer 20 established thereon. It is to be understood that the pillars P of the second retarder plate R2, 18′ are rotated at any non-zero angle with respect to the position of the pillars P of the first retarder plate R1, 18′. In an embodiment including more than two retarder plates R1, R2, 18′, it is to be understood that each retarder plate R1, R2, 18′ is rotated at any non-zero angle with respect to at least one other retarder plate R1, R2, 18′ in the stack 26.

Each of the retarder plates R1, R2, 18′ and silicon oxide or silicon oxynitride layers 20 in a stack 26 may be formed using embodiments of the methods disclosed herein. Once a desirable number of retarder plates 18′ and silicon oxide silicon oxynitride layers 20 are formed, a second substrate 28 (shown in FIGS. 2F and 4E) may be established as previously described. It is to be understood that in an embodiment with stacked retarder plate 18′, the second substrate 28 is bonded to the outermost silicon oxide or silicon oxynitride layer 20 via the second silicon oxide or silicon oxynitride layer 30.

Embodiments of the method and device 10, 10′ disclosed herein include, but are not limited to the following advantages. Unlike relatively costly polycarbonate retarders, the metal oxide retarder plate 18′ disclosed herein is able to withstand the higher temperatures resulting from the intense light path to which it is exposed. As such, the RP 18′ may be integrated directly on a lid (i.e., first substrate 14) of the device 10, 10′, thereby allowing its close proximity to a MEMS chip 22. This substantially eliminates or reduces the need for anti-reflective coatings, and the need for index-matched adhesives on either/both side(s) of the RP 18′. Furthermore, such placement may substantially reduce undesirable reflections being directed to the projected image.

While several embodiments have been described in detail, it will be apparent to those skilled in the art that the disclosed embodiments may be modified. Therefore, the foregoing description is to be considered exemplary rather than limiting.

1. An optical device, comprising:
a first substrate;
a sub-wavelength form-birefringent metal oxide retarder plate formed on at least a portion of the substrate;
a silicon oxide or silicon oxynitride layer contacting at least a surface of the retarder plate; and
a second substrate having at least one micro-electro-mechanical system chip, the second substrate being bonded to the silicon oxide or silicon oxynitride layer via a second silicon oxide or silicon oxynitride layer.

2. The optical device as defined in claim 1 wherein the retarder plate is selected from tantalum pentoxide, aluminum oxide, zinc oxide, tungsten oxide, or niobium oxide.

3. The optical device as defined in claim 1 wherein the metal oxide retarder plate has a predetermined retarder plate design including a plurality of nano-structured pillars having spaces therebetween.

4. The optical device as defined in claim 3 wherein the silicon oxide or silicon oxynitride layer is established so that the spaces are at least partially filled.

5. The optical device as defined in claim 1 wherein the at least one micro-electro-mechanical system chip is selected from light modulators, Fabry-Perot chips, micro-opto-electromechanical systems, micromirrors, micro-actuators, bio-MEMS-optical arrays, and combinations thereof.

6. The optical device as defined in claim 1 wherein the sub-wavelength form-birefringent metal oxide retarder plate is formed on a center portion of the substrate, and the optical device further comprises a metal oxide layer established on an edge of the substrate.

7. The optical device as defined in claim 1 wherein the at least one micro-electro-mechanical system chip is hermetically sealed after bonding.

8. The optical device as defined in claim 1, further comprising:
a second sub-wavelength form-birefringent metal oxide retarder plate formed on at least a portion of the silicon oxide or silicon oxynitride layer, the second sub-wavelength form-birefringent metal oxide retarder plate rotated at a non-zero angle with respect to a position of the sub-wavelength form-birefringent metal oxide retarder plate; and
a third silicon oxide or silicon oxynitride layer contacting at least a surface of the second retarder plate, wherein the second substrate is bonded to the third silicon oxide or silicon oxynitride layer via the second silicon oxide or silicon oxynitride layer.

9. The optical device as defined in claim 1 wherein the sub-wavelength form-birefringent metal oxide retarder plate is a quarter-wave plate.

10. A method for forming an optical device, comprising:
forming a metal oxide retarder plate on at least a portion of a first substrate;
establishing a silicon oxide or silicon oxynitride layer on at least a surface of the retarder plate;
planarizing the silicon oxide or silicon oxynitride layer; and
bonding the silicon oxide or silicon oxynitride layer to a second substrate via a second silicon oxide or silicon oxynitride layer, the second substrate having a micro-electro-mechanical system chip.

11. The method as defined in claim 10 wherein forming the retarder plate is accomplished by:
establishing a metal layer on the substrate;
establishing a resist layer having a predetermined retarder plate design on at least a portion of the metal layer;
selectively etching at least a portion of the metal layer to form a patterned metal layer having the predetermined retarder plate design;
removing the resist layer; and
anodically oxidizing the patterned metal layer to form the metal oxide retarder plate.

12. The method as defined in claim 11 wherein the metal layer is selectively etched to form the patterned metal layer having the predetermined retarder plate design formed in a center thereof.

13. The method as defined in claim 11 wherein establishing the resist layer on the metal layer is accomplished by:
depositing the resist layer on the metal layer; and
nano-imprinting the resist to form the predetermined retarder plate design.

14. The method as defined in claim 10 wherein forming the retarder plate is accomplished by:
establishing a metal layer on the substrate;
establishing a resist layer having a predetermined retarder plate design on at least a portion of the metal layer so that areas of the metal layer remain exposed;
anodically oxidizing the exposed areas of the metal layer, thereby forming a metal oxide having the predetermined retarder plate design;
removing the resist layer; and
removing unoxidized areas of the metal layer.

15. The method as defined in claim 10 wherein the retarder plate includes a plurality of nano-structured pillars having spaces therebetween, and wherein the silicon oxide or silicon oxynitride layer is established so that the spaces are at least partially filled.

16. The method as defined in claim 10 wherein the retarder plate has a predetermined form-birefringent property.

17. The method as defined in claim 10 wherein bonding hermetically seals the micro-electro-mechanical system chip within the optical device.

18. The method as defined in claim 10 wherein bonding is accomplished by plasma-assisted bonding or silicate bonding.

19. The method as defined in claim 10 wherein the second substrate is bonded to an outermost layer of a plurality of silicon oxide or silicon oxynitride layers, and wherein prior to bonding the second substrate, the method further comprises:
forming one of a plurality of metal oxide retarder plates on at least a portion of the silicon oxide or silicon oxynitride layer, the one of the plurality of retarder plates rotated at a non-zero angle with respect to the retarder plate;
establishing one of the plurality of silicon oxide or silicon oxynitride layers on at least a surface of the one of the plurality of retarder plates; and
planarizing the one of the plurality of silicon oxide or silicon oxynitride layers.

20. The method as defined in claim 19, further comprising;
forming an other of the plurality of metal oxide retarder plates on at least a portion of the one of the plurality of silicon oxide or silicon oxynitride layers, the other of the plurality of retarder plates rotated at a non-zero angle with respect to the retarder plate and the one of the plurality of retarder plates;
establishing an other of the plurality of second silicon oxide or silicon oxynitride layers on at least a surface of the other of the plurality of retarder plates; and
planarizing the other of the plurality of second silicon oxide or silicon oxynitride layers.
